(19) United States
(12) Patent Application Publication
(10) Pub. No.: US 2026/0173909 A1
(43) Pub. Date: Jun. 18, 2026

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Teng-Chuan Hu, Tainan City (TW); Chu-Fu Lin, Kaohsiung City (TW); Chun-Hung Chen, Tainan City (TW); Chuan-Lan Lin, Chiayi City (TW); Chiao-Hui Tu, Tainan City (TW)

(73) Assignee: UNITED MICROELECTRONICS CORP., Hsin-Chu City (TW)

(21) Appl. No.: 19/019,502

(22) Filed: Jan. 14, 2025

(30) Foreign Application Priority Data
Dec. 12, 2024 (TW) 113148326

(51) Int. Cl. H01L 23/538; H01L 21/02

(52) U.S. Cl. CPC H10W 70/611; H10P 90/123; H10W 70/635; H10W 70/65

(57) ABSTRACT

A method for fabricating semiconductor device includes first bonding a first wafer to a carrier, performing a first grinding process on a backside of the first wafer, performing a first trimming process on a sidewall of the first wafer, forming a first protective layer on the sidewall of the first wafer, forming a first bonding pad on the backside of the first wafer, bonding a second wafer to the first bonding pad, performing a second grinding process on a backside of the second wafer, performing a second trimming process on a sidewall of the second wafer, forming a second protective layer on the sidewalls of the first wafer and the second wafer, and forming a second bonding pad on the backside of the second wafer.

### BACKGROUND OF THE INVENTION

### 1. Field of the Invention

The invention relates to a method for fabricating semiconductor device, and more particularly, to a method of forming a protective layer on sidewalls of the wafer.

### 2. Description of the Prior Art

The semiconductor industry has experienced rapid growth due to continuous improvements in the integration density of various electronic components (i.e., transistors, diodes, resistors, capacitors, etc.). For the most part, this improvement in integration density has come from continuous reductions in minimum feature size, which allows more of the smaller components to be integrated into a given area. These smaller electronic components also demand smaller packages that utilize less area than previous packages. Some smaller types of packages for semiconductor components include quad flat packages (QFPs), pin grid array (PGA) packages, ball grid array (BGA) packages, flip chips (FC), three-dimensional integrated circuits (3DICs), wafer level packages (WLPs), and package on package (PoP) devices and so on.

3DICs provide improved integration density and other advantages, such as faster speeds and higher bandwidth, because of the decreased length of interconnects between the stacked chips. However, there are quite a few challenges to be handled for the technology of 3DICs.

### SUMMARY OF THE INVENTION

According to an embodiment of the present invention, a method for fabricating semiconductor device includes first bonding a first wafer to a carrier, performing a first grinding process on a backside of the first wafer, performing a first trimming process on a sidewall of the first wafer, forming a first protective layer on the sidewall of the first wafer, forming a first bonding pad on the backside of the first wafer, bonding a second wafer to the first bonding pad, performing a second grinding process on a backside of the second wafer, performing a second trimming process on a sidewall of the second wafer, forming a second protective layer on the sidewalls of the first wafer and the second wafer, and forming a second bonding pad on the backside of the second wafer.

According to another aspect of the present invention, a semiconductor device includes a second wafer bonded to a first wafer and a protective layer on sidewalls of the first wafer and the second wafer. Preferably, a thickness of the protective layer on the sidewall of the second wafer is less than a thickness of the protective layer on the sidewall of the first wafer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-13 illustrate a method for fabricating a semiconductor device according to an embodiment of the present invention.

### DETAILED DESCRIPTION

Although specific configurations and arrangements are discussed, it should be understood that this is done for illustrative purposes only. A person skilled in the pertinent art will recognize that other configurations and arrangements can be used without departing from the spirit and scope of the present disclosure. It will be apparent to a person skilled in the pertinent art that the present disclosure can also be employed in a variety of other applications.

It is noted that references in the specification to “one embodiment,” “an embodiment,”“an example embodiment,” “some embodiments,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to effect such feature, structure or characteristic in connection with other embodiments whether or not explicitly described.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,”“upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or vias are formed) and one or more dielectric layers.

Referring to FIGS. 1-13, FIGS. 1-13 illustrate a method for fabricating a semiconductor device according to an embodiment of the present invention. As shown in FIG. 1, a first wafer 12 made of semiconductor material is provided, in which the first wafer 12 includes a substrate 16 made of semiconductor materials as the substrate 16 could also be made of semiconductor substrate material including but not limited to for example silicon substrate, epitaxial silicon substrate, silicon carbide substrate or even a silicon-on-insulator (SOI) substrate, which are all within the scope of the present invention. In this embodiment, the first wafer 12 and other wafers stacked atop in the later process preferably include dynamic random access memory (DRAM) elements, but could also be used for fabricating elements including MV devices, HV devices, pixel circuits, LV devices for LV driving circuits, and/or graphics process unit (GPU).

Next, a front end of line (FEOL) and a back end of line (BEOL) fabrication processes could be conducted on the first wafer 12. In this embodiment, the FEOL process could include the process of forming metal-oxide semiconductor (MOS) transistors, oxide semiconductor field effect transistors (OS FETs), fin field effect transistor (FinFETs), or other active devices and/or passive devices. BEOL process on the other hand could include forming metal interconnect structures such as metal inter-metal dielectric (IMD) layers 18 and metal interconnections 20 on the aforementioned active devices and/or passive devices.

If a MOS transistor were to be fabricated, the FEOL process could include the steps of forming a gate structure on the substrate 16, forming a spacer (not shown) adjacent to sidewalls of the gate structure, and forming a source/drain region in the substrate 16 adjacent to two sides of the spacer, in which the gate structure could include polysilicon or metal, the spacer could include dielectric material such as silicon oxide or silicon nitride, and the source/drain region could include p-type dopants or n-type dopants depending on the conductive type of the transistor being fabricated.

Next, an interlayer dielectric (ILD) layer could be formed on the substrate 16 to cover the MOS transistor or other active devices, and then a contact plug formation and metal interconnect process from BEOL process could be conducted to form a plurality of contact plugs in the ILD layer for connecting the source/drain region and the gate structure, an inter-metal dielectric (IMD) layer 18 disposed on the ILD layer, and metal interconnections 20 in the IMD layer for connecting the contact plugs, in which the topmost metal interconnection 20 on front side of the first wafer could be used as connecting junctions such as direct bond interconnects (DBIs) for connecting to DBIs of another wafer in the later process. In this embodiment, the ILD layer and the IMD layer 18 could include oxides including but not limited to for example tetraethyl orthosilicate (TEOS) and the contact plugs and the metal interconnections 20 or DBIs could include Al, Cr, Cu, Ta, Mo, W, or combination thereof. It should be noted that through-silicon vias (TSVs) 22 are formed in the substrate 16 of the first wafer 12 to connect to the active devices and/or passive devices on the substrate 16.

Next, the first wafer 12 is reversed and bonded to a carrier 14, in which the first wafer 12 and the carrier 14 could be bonded through oxide bond, but not limited thereto. Similar to the first wafer 12, the carrier 14 could include a substrate 16 made of semiconductor materials as the substrate 16 could also be made of semiconductor substrate material including but not limited to for example silicon substrate, epitaxial silicon substrate, silicon carbide substrate or even a silicon-on-insulator (SOI) substrate. According to yet another embodiment of the present invention, the carrier 14 could also include silicon, silicon carbide, or glass, which are all within the scope of the present invention. In contrast to the first wafer 12 includes active devices and/or passive devices fabricated through FEOL or BEOL processes, the carrier 14 is preferably a blank wafer having no active devices and/or passive devices fabricated through FEOL or BEOL processes whatsoever.

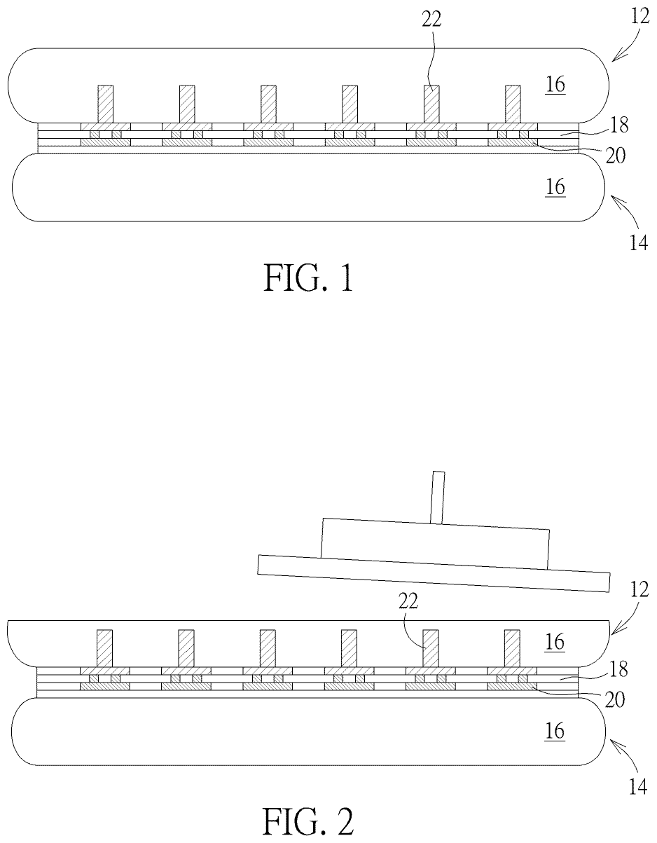

Next, as shown in FIG. 2, a grinding process is conducted on the backside of the first wafer 12 to remove part of the substrate 16 so that the overall thickness of the substrate 16 is reduced.

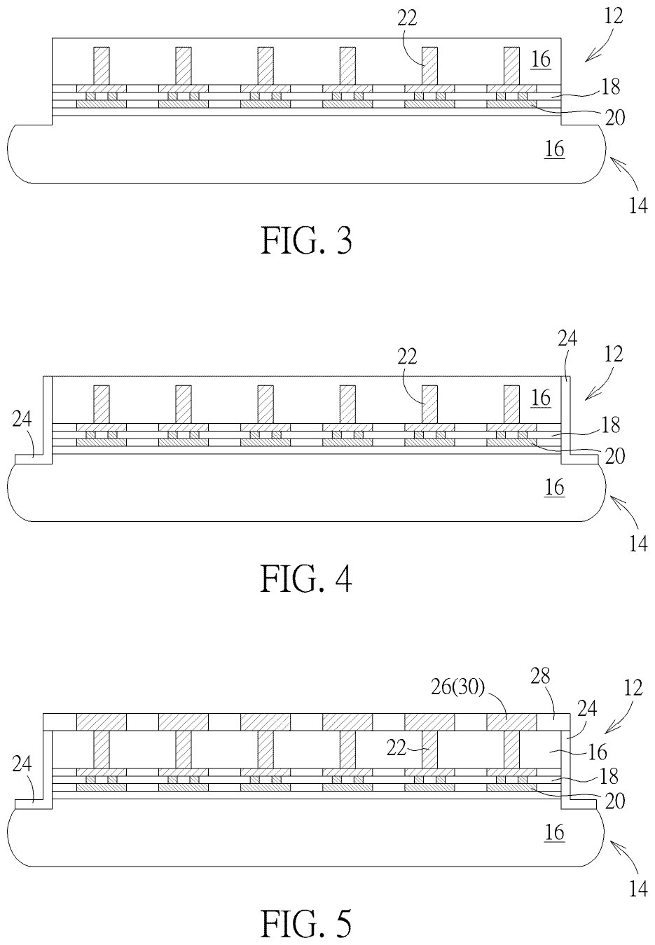

Next, as shown in FIG. 3, a trimming process is conducted on sidewalls of the first wafer 12 so that the sidewalls of the substrate 16 of the first wafer 12 are aligned with sidewalls of the IMD layer 18 and even sidewalls of part of the carrier 14.

Next, as shown in FIG. 4, a protective layer 24 is formed on sidewalls of the first wafer 12 and the carrier 14. In this embodiment, the protective layer 24 preferably includes dielectric material such as silicon nitride, silicon oxide, or combination thereof.

Next, as shown in FIG. 5, another grinding process could be conducted to remove part of the substrate 16 from backside of the first wafer 12 and expose the TSVs 22 and then form bonding pads 26 on backside of the first wafer 12. According to an embodiment of the present invention, the formation of the bonding pads 26 could be accomplished by first forming one or multiple dielectric layer 28 on the backside of the substrate 16 of the first wafer 12 and then forming metal interconnections 30 in the dielectric layer 28 through single damascene or dual damascene process, in which the metal interconnections 30 could be serving as bonding pads 26 or directly bond interconnects (DBIs) for connecting to another wafer in a hybrid bonding process. In this embodiment, the dielectric layer 28 preferably includes oxide such as tetraethyl orthosilicate (TEOS) and the bonding pads 26 or DBIs could include Al, Cr, Cu, Ta, Mo, W, or combination thereof.

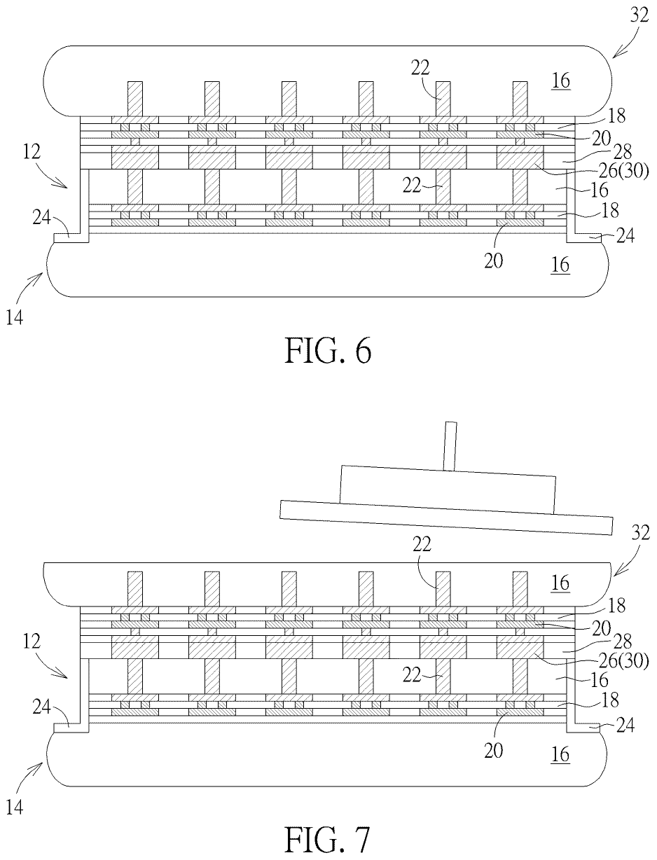

Next, as shown in FIG. 6, a second wafer 32 is provided, in which the second wafer 32 includes a substrate 16 made of semiconductor materials as the substrate 16 could also be made of semiconductor substrate material including but not limited to for example silicon substrate, epitaxial silicon substrate, silicon carbide substrate or even a silicon-on-insulator (SOI) substrate. Similar to the first wafer 12, the second wafer 32 also includes elements such as TSVs 22, ILD layer, IMD layer 18, and metal interconnections 20 fabricated through FEOL or BEOL processes, in which the topmost level metal interconnections 20 could also serve as bonding pads or DBIs for hybrid bonding process.

Next, a hybrid bonding process could be conducted to bond the first wafer 12 and second wafer 32 for forming a stack structure. Preferably, the bonding process could be accomplished by first reversing the second wafer 32 so that the front side of the second wafer 32 or the exposed surface of the metal interconnections 20 or DBIs is facing toward the front side of the first wafer 12 or the exposed surface of the metal interconnections 30, and then performing a thermal treatment process to directly bond the two wafers 12, 32 by directly contacting the metal interconnections 20, 30 on the first wafer 12 and second wafer 32 for forming a stack structure. It should be noted that even though sidewall of the IMD layer 18 of the second wafer 32 are aligned with sidewalls of the protective layer 24 adjacent to the first wafer 12, according to other embodiment of the present invention, the sidewalls of the IMD layer 18 of the second wafer 32 could also be not aligned with sidewalls of the protective layer 24 of the first wafer 12. For instance, the width of the IMD layer 18 of the second wafer 32 could be greater than the combined width of the IMD layer 18 and protective layer 24 on the first wafer 12, which is also within the scope of the present invention.

Next, as shown in FIG. 7, a grinding process is conducted on the backside of the second wafer 32 to remove part of the substrate 16 so that the overall thickness of the substrate 16 is reduced.

Next, as shown in FIG. 8, a trimming process is conducted on sidewalls of the second wafer 32 so that the sidewalls of the substrate 16 of the second wafer 32 are aligned with sidewalls of the substrate 16 of the first wafer 12.

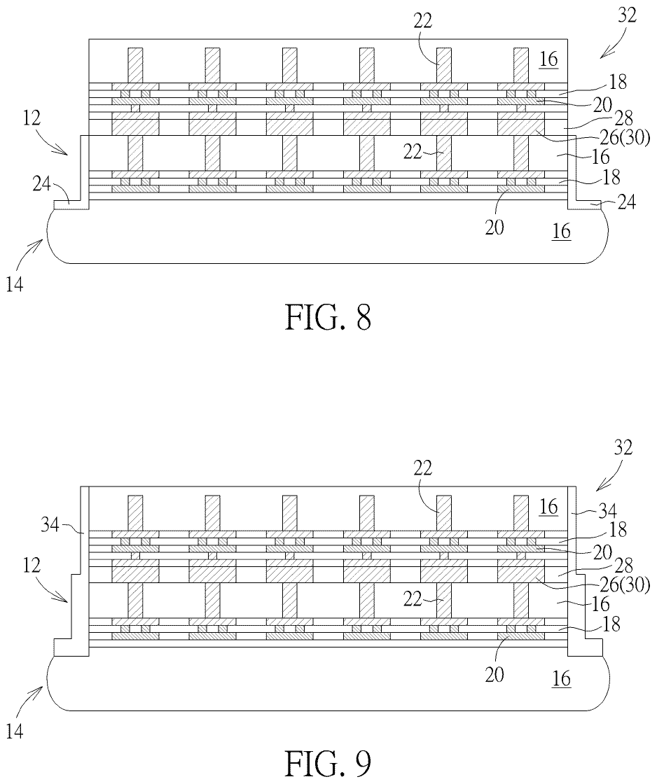

Next, as shown in FIG. 9, another protective layer (not shown) is formed on sidewalls of the first wafer 12 and sidewalls of the second wafer 32, in which the protective layer could be made of same material as the protective layer 24 formed in FIG. 4, including dielectric material such as silicon nitride, silicon oxide, or combination thereof. It should be noted that since the protective layer formed at this stage and the aforementioned protective layer 24 are preferably made of same material, after the protective layer is formed on sidewalls of the first wafer 12 and second wafer 32 at this stage, the two protective layers preferably combine to form a new protective layer 34 as the thickness of the protective layer 34 on sidewalls of the second wafer 32 is less than the thickness of the protective layer 34 on sidewalls of the first wafer 12. In other words, since the protective layer 24 is already formed on sidewalls of the first wafer 12 in FIG. 4, after the protective layer 34 is formed at this stage, the sidewalls of the second wafer 32 would only include a thickness of single protective layer while the sidewalls of the first wafer 12 would include a thickness of dual protective layers.

According to an embodiment of the present invention, the thickness of the protective layer formed at this stage is substantially equal to the thickness of the protective layer 24 formed in FIG. 4. Hence, after the protective layer 34 is formed at this stage, the thickness of the protective layer 34 on a sidewall or sidewalls of the first wafer 12 is twice the thickness of the protective layer 34 on a sidewall or sidewalls of the second wafer 32. Moreover, the thickness of the protective layer 34 could also be defined as a width of the protective layer 34 if viewed from a cross-section perspective.

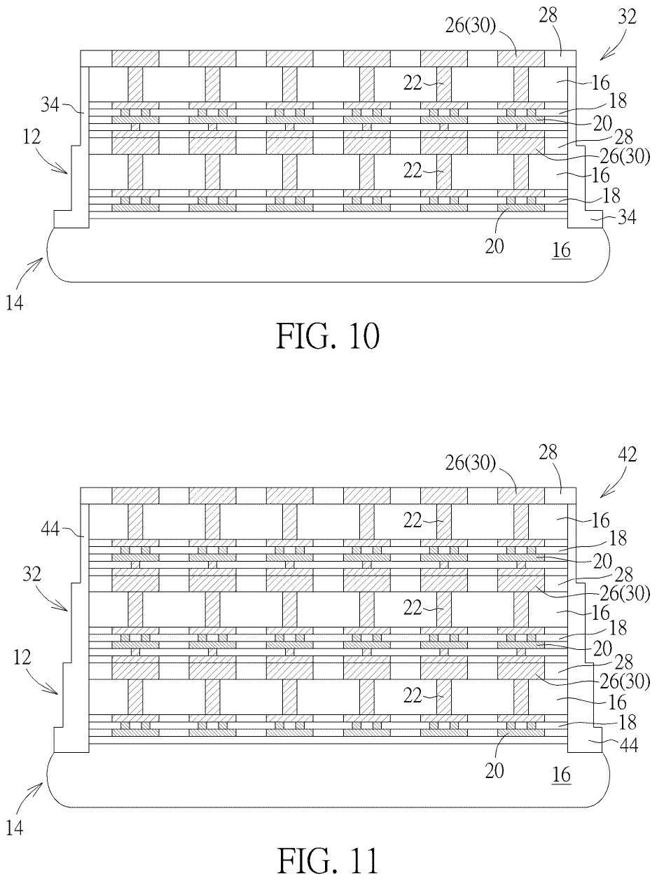

Next, as shown in FIG. 10, another grinding process could be conducted to remove part of the substrate 16 from backside of the second wafer 32 and expose the TSVs 22 and then form bonding pads 26 on backside of the first wafer 12. Similar to the process conducted in FIG. 5, the formation of the bonding pads 26 could be accomplished by first forming one or multiple dielectric layer 28 on the backside of the substrate 16 of the second wafer 32 and then forming metal interconnections 30 in the dielectric layer 28 through single damascene or dual damascene process, in which the metal interconnections 30 could be serving as bonding pads 26 or directly bond interconnects (DBIs) for connecting to another wafer in a hybrid bonding process. In this embodiment, the dielectric layer 28 preferably includes oxide such as tetraethyl orthosilicate (TEOS) and the bonding pads 26 or DBIs could include Al, Cr, Cu, Ta, Mo, W, or combination thereof.

Next, as shown in FIG. 11, fabrication processes conducted in FIG. 6 could be repeated by bonding a third wafer 42 to the backside of the second wafer 32. Similar to the first wafer 12 and second wafer 32, the third wafer 42 also includes elements such as TSVs 22, ILD layer, IMD layer 18, and metal interconnections 20 fabricated through FEOL or BEOL processes, in which the topmost level metal interconnections 20 could also serve as bonding pads or DBIs for hybrid bonding process.

Next, processes conducted in FIGS. 7-10 could be repeated by conducting a grinding process to remove part of the substrate 16 of the third wafer 42 so that the overall thickness of the substrate 16 is reduced, conducting a trimming process on sidewalls of the third wafer 42 so that the sidewalls of the substrate 16 of the third wafer 42 are aligned with sidewalls of the substrates 16 of the first wafer 12 and second wafer 32, and then forming another protective layer on sidewalls of the first wafer 12, second wafer 32, and third wafer 42. Similar to the aforementioned protective layers formed in FIGS. 4 and 9, the protective layer formed at this stage could include dielectric material such as silicon nitride, silicon oxide, or combination thereof.

Since the protective layer formed at this stage and the aforementioned protective layer are preferably made of same material, after the protective layer is formed on sidewalls of the first wafer 12, sidewalls of the second wafer 32, and sidewall of the third wafer 42 at this stage, the three protective layers preferably combine to form a new protective layer 44 as the thickness of the protective layer 44 on sidewalls of the third wafer 42 is less than the thickness of the protective layer 44 on sidewalls of the second wafer 32 and the thickness of the protective layer 44 on sidewalls of the second wafer 32 is further less than the thickness of the protective layer 44 on sidewalls of the first wafer 12. In other words, since the protective layer 34 is already formed on sidewalls of the first wafer 12 and second wafer 32 in FIG. 9, after the protective layer 44 is formed at this stage, the sidewalls of the third wafer 42 would only include a thickness of single protective layer while the sidewalls of the second wafer 32 would include a thickness of dual protective layers and the sidewalls of the first wafer 12 would include a thickness of triple protective layers.

According to an embodiment of the present invention, the thickness of the protective layer formed at this stage is substantially equal to the thickness of the protective layer 24 formed in FIG. 4. Hence, after the protective layer 44 is formed at this stage, the thickness of the protective layer 44 on a sidewall or sidewalls of the first wafer 12 is three times the thickness of the protective layer 44 on a sidewall or sidewalls of the third wafer 42 and the thickness of the protective layer 44 on a sidewall or sidewalls of the second wafer 32 is twice the thickness of the protective layer 44 on a sidewall or sidewalls of the third wafer 42. If viewed from a cross-section perspective, the protective layer 44 preferably includes step portions on sidewalls of the three wafers and the width of the protective layer 44 closer to the bottom is greater than the width of the protective layer 44 closer to the top.

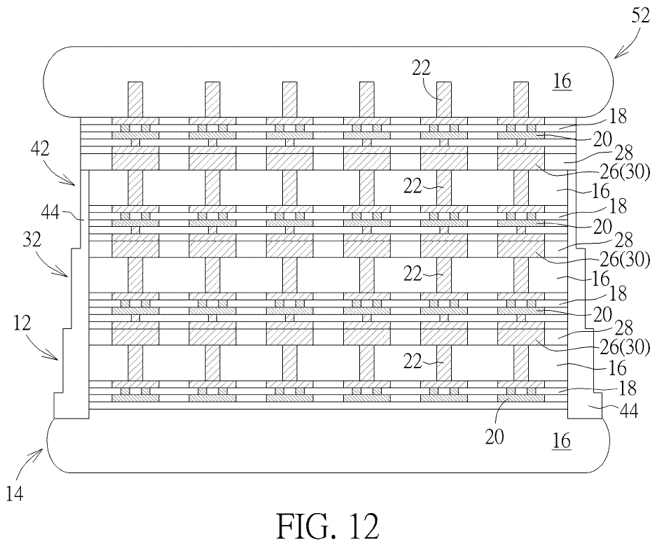

Next, as shown in FIG. 12, fabrication process conducted in FIG. 6 could be repeated by bonding a fourth wafer 52 to the backside of the third wafer 42. Similar to the first wafer 12, the second wafer 32, and the third wafer 42, the fourth wafer 52 also includes elements such as TSVs 22, ILD layer, IMD layer 18, and metal interconnections 20 fabricated through FEOL or BEOL processes, in which the topmost level metal interconnections 20 could also serve as bonding pads or DBIs for hybrid bonding process.

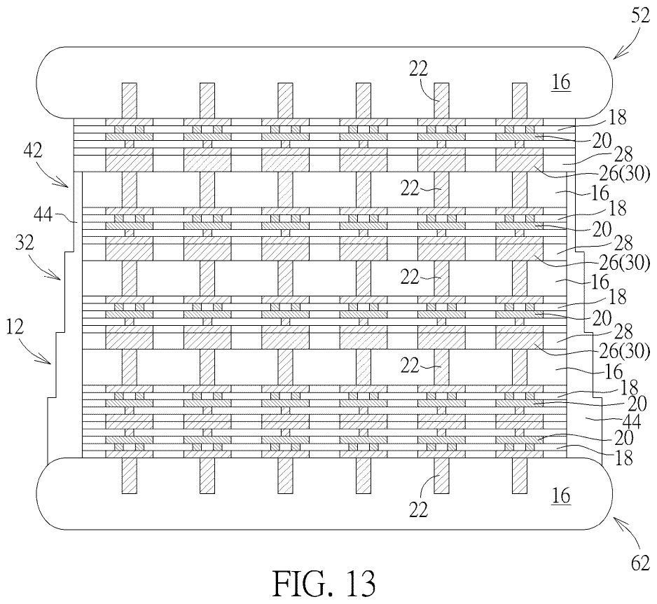

Next, as shown in FIG. 13, a grinding process and/or etching process could be conducted to remove the carrier 14 and then bonding a fifth wafer 62 to the front side of the first wafer 12. Similar to the first wafer 12 and second wafer 32, the fifth wafer 62 also includes elements such as TSVs 22, ILD layer, IMD layer 18, and metal interconnections 20 fabricated through FEOL or BEOL processes, in which the topmost level metal interconnections 20 could also serve as bonding pads or DBIs as the first wafer 12 and the fifth wafer 62 could be bonded or connected to each other through hybrid bonding process. According to a preferred embodiment of the present invention, the fifth wafer 62 is preferably a logic chip while the aforementioned first wafer 12 to fourth wafer 52 altogether constitute a DRAM stack structure. This completes the fabrication of a semiconductor device.

Overall, the present invention discloses a wafer to wafer stacking technique for high bandwidth memory (HBM), which first bonds a first wafer 12 to a temporary carrier 14, conducts a first grinding process on backside of the first wafer, conducts a first trimming process on sidewalls of the first wafer, forms a first protective layer 24 on sidewalls of the first wafer, forms first bonding pads on backside of the first wafer, bonds a second wafer 32 to the first wafer, conducts a second grinding process on backside of the second wafer, conducts a second trimming process on sidewalls of the second wafer, forms a second protective layer 34 on sidewalls of the first wafer and second wafer, and then forms second bonding pads on backside of the second wafer. Next, the aforementioned wafer bonding, grinding, and trimming processes could be repeated to form a stack structure made of multiple wafers, the carrier is removed, and then a logic wafer is bonded to the first wafer. Since a protective layer is formed on sidewalls of the wafers each time after a new wafer is bonded, the thickness of the protective layer on sidewalls of the lower level wafers (such as the first wafer) would therefore be greater than the thickness of the protective layer on sidewalls of the upper level wafers (such as the second wafer or the third wafer).

According to an embodiment of the present invention, means for bonding between wafers and/or stack structures could be accomplished by but not limited to for example hybrid bonding process, micro bump bonding process, or gold bump process. By first stacking wafers to form stack structures and then conducting chip probing (CP) test and repair procedures through the TSVs, RDL, bonding pads, and bumps on the stack structure, it would be desirable to reduce cycle time and overall cost than conventional approach of first conducting CP test and then stacking wafers afterwards.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating semiconductor device, comprising:
bonding a first wafer to a carrier;
performing a first grinding process on a backside of the first wafer;
performing a first trimming process on a sidewall of the first wafer;
forming a first protective layer on the sidewall of the first wafer; and
forming a first bonding pad on the backside of the first wafer.

2. The method of claim 1, wherein the first wafer comprises first through-silicon vias (TSVs), the method further comprising:
exposing the first TSVs after forming the first protective layer.

3. The method of claim 2, further comprising exposing the first TSVs before forming the first bonding pad.

4. The method of claim 2, further comprising:
bonding a second wafer to the first wafer;
performing a second grinding process on a backside of the second wafer;
performing a second trimming process on a sidewall of the second wafer;
forming a second protective layer on the sidewalls of the first wafer and the second wafer; and
forming a second bonding pad on the backside of the second wafer.

5. The method of claim 4, wherein the second wafer comprises second through-silicon vias (TSVs), the method further comprising:
exposing the second TSVs after forming the second protective layer.

6. The method of claim 4, further comprising exposing the second TSVs before forming the second bonding pad.

7. The method of claim 4, wherein the sidewall of the first wafer and the sidewall of the second wafer are aligned.

8. The method of claim 1, wherein the carrier comprises a silicon wafer.

9. A semiconductor device, comprising:
a second wafer bonded to a first wafer; and
a protective layer on sidewalls of the first wafer and the second wafer, wherein a thickness of the protective layer on the sidewall of the second wafer is less than a thickness of the protective layer on the sidewall of the first wafer.

10. The semiconductor device of claim 9, further comprising:
a third wafer bonded to the second wafer; and
the protective layer on sidewalls of the first wafer, the second wafer, and the third wafer, wherein a thickness of the protective layer on the sidewall of the third wafer is less than a thickness of the protective layer on the sidewall of the second wafer.

11. The semiconductor device of claim 10, wherein the sidewall of the second wafer and the sidewall of the third wafer are aligned.

12. The semiconductor device of claim 9, wherein the sidewall of the first wafer and the sidewall of the second wafer are aligned.
